(19) United States
(12) Patent Application Publication
(10) Pub. No.: US 2024/0417582 A1
(43) Pub. Date: Dec. 19, 2024

(54) ELECTRICALLY CONDUCTIVE SILICONE COMPOSITION WITH CARBON NANOTUBES AND CARBON BLACK

(71) Applicant: WACKER CHEMIE AG, Munich (DE)

(72) Inventor: Sabin-Lucian SURARU, Munich (DE)

(73) Assignee: WACKER CHEMIE AG, Munich (DE)

(21) Appl. No.: 18/700,843

(22) PCT Filed: Oct. 13, 2021
(86) PCT No.: PCT/EP2021/078323

§ 371 Date: Apr. 12, 2024

(51) Int. Cl. C09D 11/52; C09D 11/037; C09D 11/102; H01B 1/24

(52) U.S. Cl. CPC C09D 11/52; C09D 11/037; C09D 11/102; H01B 1/24

(57) ABSTRACT

An electrically conductive, crosslinking silicone elastomer composition is provided including carbon black in an amount of 0.5% to 3.0%, wherein the carbon black has a BET surface area of at most 300 m²/g. The electrically conductive, crosslinking silicone elastomer composition further includes carbon nanotubes (CNTs) in an amount of 0.1% to 3.0% by weight. The electrically conductive, crosslinking silicone elastomer composition does not include any solvent.

The invention relates to electrically conductive, crosslinking silicone elastomer compositions, to a process for the production thereof and to the use thereof as electrically conductive printing ink in contactless printing processes to produce electrodes for sensors, actuators or EAP layer systems.

Electrically conductive printing inks are used for the production of printed electronics, in order, in electronic components, to apply electrodes over a large area or in a structured fashion to a substrate by way of any desired printing process. The printing of electrically conductive elastomers on an elastic support (such as silicone, TPU) enables the construction of completely or partially elastic electronic components that maintain the electrical properties virtually unchanged even in the case of stretching or compression. In addition, electrically conductive elastomer printing inks can be printed on flexible (but not stretchable) substrates, such as on PET, PE, PTFE or paper, in order, even in the case of sustained mechanical loading by repeated bending, to keep the mechanical damage to the printed electrode low and therefore to prevent a change in the electrical conductivity due to an increase in the resistance, for example. Conductive printing inks for printed electronics are known and some of them are also commercially available. They typically comprise at least one polymeric binder, at least one conductive component such as metal particles or carbon particles, and at least one solvent to adjust the viscosity. In principle, as filler, conductive carbon particles such as carbon black and carbon nanotubes (CNTs) have the disadvantage that they significantly raise the viscosity of the formulation, this making it much more difficult to print the ink, with the result that dilution solvents are typically used in order to reduce the effective concentration of the particles in the printing ink and to thus make it possible for the printing ink to be applied. US2016351289 describes that there must be a solvent content of at least 10% in a silicone-based conductive printing ink in order to be able to apply said ink. Typically, in the field of silicone printing inks use is made of organic solvents which can subsequently be completely removed only with great difficulty and which entail high costs for the user with respect to occupational safety and environmental protection.

For highly conductive applications, carbon black is usually also added to a CNT-containing formulation, since this typically causes a less strongly pronounced viscosity increase than CNTs do, the conductivity of the electrode is improved and a more homogeneous charge distribution in the electrode of the final component is ensured. Carbon blacks which feature a high surface area and structure are typically used for highly conductive materials with low specific resistance of <10-100 Ohm*cm. The conductivity of carbon black typically increases as the surface area increases. BET measurements of highly conductive carbon blacks typically give values of >800 m²/g in this case. One typical example of this is Ketjenblack EC600JD (BET 1400 m²/g). Carbon blacks with smaller surface areas (BET<300 m²/g) have to be used in a larger proportion by volume and by mass in the overall formulation and bring about lower electrical conductivity. Furthermore, typically >20% by weight of carbon black is needed in order for the specific resistance to go well below 100 Ωcm.

U.S. Pat. No. 9,253,878 describes such a formulation having a solids content of 28% by weight, based on a silicone elastomer, carbon black and CNTs, the latter being characterized in that they have a thickness of at least 30 nm. The latter property imparts good printability in screen printing to the solvent-containing, conductive printing ink, this not being possible with thin CNTs (<30 nm). Used in the examples is the highly conductive carbon black Ketjenblack EC300J (manufacturer specifications: BET 800 m²/g; OAN 310-345 ml/100 g). The printing ink described in U.S. Pat. No. 9,253,878 exhibits very good electrical conductivities of <1 Ohm*cm.

CNT-containing silicone elastomers are known. CN103160128 describes silicone elastomers comprising both CNTs and carbon black. The silicone elastomers described in this document feature a high proportion of carbon black. The carbon black additionally features a high surface area (BET 1400-1500 m²/g). Claimed is at least 3.7% by weight of carbon black; however, the examples show that a total filler content (CB+CNT) of at least 8.5% is needed to obtain good electrical properties such that the specific resistance is <20 Ohm*cm. There is no disclosure of any printing process using these compositions.

Only a few solvent-free silicone-based printing inks are known: for example, US2014060903 describes a solvent-free, silicone-based, conductive printing ink that however does not contain any conductive particles with a high aspect ratio (such as carbon nanotubes=CNTs) and is therefore not suitable for stretchable applications. For stretchable applications, including the dielectric elastomer sensors, actuators and generators, use is made of stretchable binders (elastomers) in combination with conductive anisotropic particles that have a high aspect ratio, typically CNTs. The high aspect ratio of the conductive particles ensures that the conductive particles, in contrast to spherical particles, can form a conductive network through the entire system at relatively low filler amounts, this network remaining even when the elastomer is stretched. Good electron conduction is therefore still guaranteed even when the elastomer is stretched.

The processes known in the prior art for applying silicone layers, particularly those suitable for the production of electrode layers and/or dielectric layers in actuators, sensors and other electroactive polymer layer systems, are limited in terms of their variability, application accuracy, throughput, and in terms of the component effectiveness and durability that are subsequently achieved.

One of the processes known in the prior art for the application of layers is that referred to as laser transfer printing. However, the application of this process has so far been limited to low-viscosity inks and dispersions, and metals.

By way of example, WO 2009/153192 A2 describes a process for producing conductive layers on semiconductor structures, where a metal powder dispersion is applied to a support and detached from the support onto a target by way of a laser beam.

By way of example, WO 2010/069900 A1 describes the laser transfer printing of ink.

WO 2015/181810 A1 describes a laser transfer process for printing metallic bodies. This involves selectively heating a metal film on a transparent support and positioning it in the form of drops.

The object of the present invention was to provide electrically conductive, crosslinking silicone elastomer compositions with a specific resistance of <10 Ohm*cm, which requires small amounts of carbon black in combination with CNTs, but not the use of solvents, and at the same time exhibits good application properties as printing ink in pressureless application processes such as the laser transfer printing process.

It has surprisingly been found that it is sufficient to add a carbon black with an only relatively small surface area (BET of at most 300 m²/g) in only small amounts (at most 3% by weight) to the CNT-containing silicone elastomer composition according to the invention, without this having a negative effect on the electrical properties of an electrode produced therewith. The viscosity of the silicone elastomer composition according to the invention is at most 60 000 mPas at a shear rate of 10 s⁻¹. It is therefore possible to use said composition as printing ink to print electrodes for dielectric elastomer sensors, actuators and generators without adding a solvent. Furthermore, the stretching factor of the relative resistance increase R/R₀ is lowered.

In order not to create an excessive number of pages in the description of the present invention, only the preferred embodiments of the individual features are specified hereinafter.

However, the expert reader should explicitly understand this manner of disclosure such that any combination of different levels of preference is thus also explicitly disclosed and explicitly desired.

The invention therefore provides an electrically conductive, crosslinking silicone elastomer composition comprising:
0.5% to 3.0% by weight of carbon black with a BET surface area of at most 300 m²/g,
0.1% to 3.0% by weight of carbon nanotubes (CNTs), NO solvent.

Base materials used for the silicone elastomer composition may in principle be all silicone elastomer compositions known in the prior art.

By way of example, addition-crosslinking, peroxide-crosslinking, condensation-crosslinking or radiation-crosslinking silicone elastomer compositions may be used. Preference is given to peroxide- or addition-crosslinking compositions. Particular preference is given to addition-crosslinking compositions.

The silicone elastomer compositions may have a one-component or two-component formulation. The silicone elastomer compositions are crosslinked here by supply of heat, UV light and/or moisture.

By way of example, the following silicone elastomer compositions are suitable: HTV (addition-crosslinking), HTV (radiation-crosslinking), LSR, RTV 2 (addition-crosslinking), RTV 2 (condensation-crosslinking), RTV 1, TPSE (thermoplastic silicone elastomer), thiol-ene and cyanoacetamide-crosslinking systems.

In the simplest case, the preferred addition-crosslinking silicone elastomer compositions comprise:
(A) at least one linear compound comprising radicals having aliphatic carbon-carbon multiple bonds,
(B) at least one linear organopolysiloxane compound having Si-bonded hydrogen atoms, or, instead of (A) and (B) or in addition to (A) and (B),
(C) at least one linear organopolysiloxane compound comprising Si—C-bonded radicals having aliphatic carbon-carbon multiple bonds and Si-bonded hydrogen atoms, and
(D) at least one hydrosilylation catalyst.

The silicone compositions may be either one-component silicone compositions or two-component silicone compositions. In the latter case, the two components of the compositions according to the invention may comprise all constituents in any desired combination, generally with the proviso that one component does not simultaneously comprise siloxanes having an aliphatic multiple bond, siloxanes having Si-bonded hydrogen and catalyst, i.e. essentially does not simultaneously comprise constituents (A), (B) and (D) or (C) and (D).

As is well known, compounds (A) and (B) or (C) used in the compositions according to the invention are selected such that crosslinking is possible. For example, compound (A) thus has at least two aliphatically unsaturated radicals and (B) has at least three Si-bonded hydrogen atoms, or compound (A) has at least three aliphatically unsaturated radicals and siloxane (B) has at least two Si-bonded hydrogen atoms, or else, instead of compound (A) and (B), siloxane (C) having aliphatically unsaturated radicals and Si-bonded hydrogen atoms in the abovementioned ratios is used. Mixtures of (A) and (B) and (C) having the abovementioned ratios of aliphatically unsaturated radicals and Si-bonded hydrogen atoms are also.

Compound (A) used according to the invention may be silicon-free organic compounds having preferably at least two aliphatically unsaturated groups, and organosilicon compounds having preferably at least two aliphatically unsaturated groups, or else mixtures thereof.

Examples of silicon-free organic compounds (A) are 1,3,5-trivinylcyclohexane, 2,3-dimethyl-1,3-butadiene, 7-methyl-3-methylene-1,6-octadiene, 2-methyl-1,3-butadiene, 1,5-hexadiene, 1,7-octadiene, 4,7-methylene-4,7,8,9-tetrahydroindene, methylcyclopentadiene, 5-vinyl-2-norbornene, bicyclo[2.2.1]hepta-2,5-diene, 1,3-diisopropenylbenzene, polybutadiene containing vinyl groups, 1,4-divinylcyclohexane, 1,3,5-triallylbenzene, 1,3,5-trivinylbenzene, 1,2,4-trivinylcyclohexane, 1,3,5-triisopropenylbenzene, 1,4-divinylbenzene, 3-methyl-1,5-heptadiene, 3-phenyl-1,5-hexadiene, 3-vinyl-1,5-hexadiene and 4,5-dimethyl-4,5-diethyl-1,7-octadiene, N,N′-methylenebisacrylamide, 1,1,1-tris(hydroxymethyl)propane triacrylate, 1,1,1-tris(hydroxymethyl)propane trimethacrylate, tripropylene glycol diacrylate, diallyl ether, diallylamine, diallyl carbonate, N,N′-diallylurea, triallylamine, tris(2-methylallyl)amine, 2,4,6-triallyloxy-1,3,5-triazine, triallyl-s-triazine-2,4,6(1H,3H,5H)-trione, diallyl malonate, polyethylene glycol diacrylate, polyethylene glycol dimethacrylate, poly(propylene glycol) methacrylate.

The silicone compositions according to the invention preferably comprise, as constituent (A), at least one aliphatically unsaturated organosilicon compounds, it being possible to use all aliphatically unsaturated organosilicon compounds used to date in addition-crosslinking compositions, such as silicone block copolymers having urea segments, silicone block copolymers having amide segments and/or imide segments and/or ester amide segments and/or polystyrene segments and/or silarylene segments and/or carborane segments and silicone graft copolymers having ether groups.

Organosilicon compounds (A) used that comprise Si—C-bonded radicals having aliphatic carbon-carbon multiple bonds are preferably linear or branched organopolysiloxanes composed of units of the general formula (I)

R⁴ₐR⁵_{b}SiO_{(4-a-b)/2} (I),
where
R⁴ independently at each occurrence is identical or different and is an organic or inorganic radical free of aliphatic carbon-carbon multiple bonds,
R⁵ independently at each occurrence is identical or different and is a monovalent, substituted or unsubstituted, Si—C-bonded hydrocarbon radical having at least one aliphatic carbon-carbon multiple bond,
a is 0, 1, 2 or 3, and
b is 0, 1 or 2,
with the proviso that the sum total of a+b is less than or equal to 3 and there are at least 2 radicals R⁵ per molecule.

Radical R⁴ may be mono- or polyvalent radicals, where the polyvalent radicals, such as bivalent, trivalent and tetravalent radicals, then connect multiple, for instance two, three or four, siloxy units of the formula (I) to one another.

Further examples of R⁴ are the monovalent radicals —F, —Cl, —Br, —OR⁶, —CN, —SCN, —NCO and Si—C-bonded, substituted or unsubstituted hydrocarbon radicals which may be interrupted by oxygen atoms or the group —C(O)—, and divalent radicals Si-bonded at both ends as per formula (I). If radical R⁴ is Si—C-bonded, substituted hydrocarbon radicals, preferred substituents are halogen atoms, phosphorus-containing radicals, cyano radicals, —OR⁶, —NR⁶—, —NR⁶₂, —NR⁶—C(O)—NR⁶₂, —C(O)—NR⁶₂, —C(O)R⁶, —C(O)OR⁶, —SO₂-Ph and —C₆F₅. In this case, R⁶ are independently at each occurrence identical or different and are a hydrogen atom or a monovalent hydrocarbon radical having 1 to 20 carbon atoms and Ph is the phenyl radical.

Examples of radicals R⁴ are alkyl radicals, such as the methyl, ethyl, n-propyl, isopropyl, n-butyl, isobutyl, tert-butyl, n-pentyl, isopentyl, neopentyl, tert-pentyl radical, hexyl radicals, such as the n-hexyl radical, heptyl radicals, such as the n-heptyl radical, octyl radicals, such as the n-octyl radical, and isooctyl radicals, such as the 2,2,4-trimethylpentyl radical, nonyl radicals, such as the n-nonyl radical, decyl radicals, such as the n-decyl radical, dodecyl radicals, such as the n-dodecyl radical, and octadecyl radicals, such as the n-octadecyl radical, cycloalkyl radicals, such as cyclopentyl, cyclohexyl, cycloheptyl and methylcyclohexyl radicals, aryl radicals, such as the phenyl, naphthyl, anthryl and phenanthryl radical, alkaryl radicals, such as o-, m-, p-tolyl radicals, xylyl radicals and ethylphenyl radicals, and aralkyl radicals, such as the benzyl radical, the α- and the β-phenylethyl radical.

Examples of substituted radicals R⁴ are haloalkyl radicals, such as the 3,3,3-trifluoro-n-propyl radical, the 2,2,2,2′,2′,2′-hexafluoroisopropyl radical, the heptafluoroisopropyl radical, haloaryl radicals, such as the o-, m- and p-chlorophenyl radical, —(CH₂)—N(R⁶)C(O)NR⁶₂, —(CH₂)ₙ—C(O)NR⁶₂, —(CH₂)ₒ—C(O)R⁶, —(CH₂)ₒ—C(O)OR⁶, —(CH₂)ₒ—C(O)NR⁶₂, —(CH₂)—C(O)—(CH₂)ₚC(O) CH₃, —(CH₂)—O—CO—R⁶, —(CH₂)—NR⁶—(CH₂)ₚ—NR⁶₂, —(CH₂)ₒ—O—(CH₂)ₚCH (OH) CH₂OH, —(CH₂)ₒ(OCH₂CH₂)ₚOR⁶, —(CH₂)ₒ—SO₂-Ph and —(CH₂)ₒ—O—C₆F₅, where R⁶ and Ph corresponds to the definition given for them above and o and p are identical or different integers between 0 and 10.

Examples of R⁴ as divalent radicals Si-bonded at both ends as per formula (I) are those that derive from the monovalent examples given above for radical R⁴ in that there is an additional bond through substitution of a hydrogen atom; examples of such radicals are —(CH₂)—, —CH(CH₃)—, —C(CH₃)₂—, —CH(CH₃)—CH₂—, —C₆H₄—, —CH(Ph)-CH₂—, —C(CF₃)₂—, —(CH₂)ₒ—C₆H₄—(CH₂)ₒ—, —(CH₂)ₒ—C₆H₄—C₆H₄—(CH₂)ₒ—, —(CH₂O)ₚ, (CH₂CH₂O)ₒ, —(CH₂)ₒ-Oₓ-C₆H₄—SO₂—C₆H₄—Oₓ—(CH₂)ₒ—, where x is 0 or 1, and Ph, o and p have the definition given above.

Radical R⁴ is preferably a monovalent, Si—C-bonded, optionally substituted hydrocarbon radical that is free of aliphatic carbon-carbon multiple bonds and has 1 to 18 carbon atoms, particularly preferably a monovalent, Si—C-bonded hydrocarbon radical that is free of aliphatic carbon-carbon multiple bonds and has 1 to 6 carbon atoms, in particular the methyl or phenyl radical.

Radical R⁵ from formula (I) may be any desired groups that are amenable to an addition reaction (hydrosilylation) with an SiH-functional compound.

If radical R⁵ is Si—C-bonded, substituted hydrocarbon radicals, preferred substituents are halogen atoms, cyano radicals and —OR⁶, where R⁶ has the definition given above.

Radical R⁵ is preferably alkenyl and alkynyl groups having 2 to 16 carbon atoms, such as vinyl, allyl, methallyl, 1-propenyl, 5-hexenyl, ethynyl, butadienyl, hexadienyl, cyclopentenyl, cyclopentadienyl, cyclohexenyl, vinylcyclohexylethyl, divinylcyclohexylethyl, norbornenyl, vinylphenyl and styryl radicals, particular preference being given to the use of vinyl, allyl and hexenyl radicals.

The molecular weight of constituent (A) may vary within wide limits, for instance between 10² and 10⁶ g/mol. For example, constituent (A) may thus be an alkenyl-functional oligosiloxane of relatively low molecular weight, such as 1,2-divinyltetramethyldisiloxane, but also a high-polymeric polydimethylsiloxane having Si-bonded vinyl groups in chain or terminal positions, for example having a molecular weight of 105 g/mol (number average determined by means of NMR). The structure of the molecules forming constituent (A) is not fixed either; in particular, the structure of a siloxane of relatively high molecular weight, i.e. an oligomeric or polymeric siloxane, may be linear, cyclic, branched or else resinous, network-like. Linear and cyclic polysiloxanes are preferably composed of units of the formula R⁴₃SiO_{1/2}, R⁵R⁴₂SiO_{1/2}, R⁵R⁴SiO_{1/2} and R⁴₂SiO_{2/2}, where R⁴ and R⁵ have the definition given above. Branched and network-like polysiloxanes additionally comprise trifunctional and/or tetrafunctional units, preference being given to those of the formulae R⁴SiO_{3/2}, R⁵SiO_{3/2} and SiO_{4/2}. It is of course also possible to use mixtures of different siloxanes that meet the criteria of constituent (A).

Particularly preferred as component (A) is the use of vinyl-functional, essentially linear polydiorganosiloxanes having a viscosity of 0.01 to 500 000 Pa·s, particularly preferably of 0.1 to 100 000 Pa·s, in each case at 25° C., measured in accordance with DIN EN ISO 3219:1994 and DIN 53019 using a calibrated rheometer with a cone/plate system, cone CP50-2 with an opening angle of 2° and a shear rate of 1 s⁻¹.

Organosilicon compounds (B) used may be all hydrogen-functional organosilicon compounds that have also been used to date in addition-crosslinkable compositions.

Organopolysiloxanes (B) used that have Si-bonded hydrogen atoms are preferably linear, cyclic or branched organopolysiloxanes composed of units of the general formula (III)

R⁴_{c}H_{d}SiO_{(4-c-d)/2} (III),
where
R⁴ has the definition given above,
c is 0.1 2 or 3 and
d is 0, 1 or 2,
with the proviso that the sum total of c+d is less than or equal to 3 and there are at least two Si-bonded hydrogen atoms per molecule.

The organopolysiloxane (B) used according to the invention preferably comprises Si-bonded hydrogen in the range from 0.04 to 1.7 percent by weight, based on the total weight of the organopolysiloxane (B).

The molecular weight of constituent (B) may likewise vary within wide limits, for instance between 10² and 10⁶ g/mol. For example, constituent (B) may thus be an SiH-functional oligosiloxane of relatively low molecular weight, such as tetramethyldisiloxane, but also a high-polymeric polydimethylsiloxane having SiH groups in chain or terminal positions or a silicone resin having SiH groups.

The structure of the molecules forming constituent (B) is not fixed either; in particular, the structure of an SiH-containing siloxane of relatively high molecular weight, i.e. an oligomeric or polymeric SiH-containing siloxane, may be linear, cyclic, branched or else resinous, network-like. Linear and cyclic polysiloxanes (B) are preferably composed of units of the formula R⁴₃SiO_{1/2}, HR⁴₂SiO_{1/2}, HR⁴SiO_{2/2} and R⁴₂SiO_{2/2}, where R⁴ has the definition given above. Branched and network-like polysiloxanes additionally comprise trifunctional and/or tetrafunctional units, preference being given to those of the formulae R⁴SiO_{3/2}, HSiO_{3/2} and SiO_{4/2}, where R⁴ has the definition given above.

It is of course also possible to use mixtures of different siloxanes that meet the criteria of constituent (B). In particular, the molecules forming constituent (B) may optionally at the same time also comprise aliphatically unsaturated groups in addition to the obligatory SiH groups. Particularly preferred is the use of SiH-functional compounds of low molecular weight such as tetrakis(dimethylsiloxy)silane and tetramethylcyclotetrasiloxane, and SiH-containing siloxanes of relatively high molecular weight, such as poly(hydrogenmethyl)siloxane and poly(dimethylhydrogenmethyl)siloxane, having a viscosity at 25° C. of 10 to 20 000 mPa·s, measured in accordance with DIN EN ISO 3219:1994 and DIN 53019 using a calibrated rheometer with a cone/plate system, cone CP50-2 with an opening angle of 2° and a shear rate of 1 s⁻¹, or analogous SiH-containing compounds in which some of the methyl groups have been replaced by 3,3,3-trifluoropropyl or phenyl groups.

Constituent (B) is preferably present in the crosslinkable silicone compositions according to the invention in such an amount that the molar ratio of SiH groups to aliphatically unsaturated groups from (A) is 0.1 to 20, particularly preferably between 0.3 and 2.0.

Components (A) and (B) used according to the invention are commercially available products or can be prepared by standard processes.

Instead of component (A) and (B), the silicone compositions according to the invention may comprise organopolysiloxanes (C) comprising at the same time aliphatic carbon-carbon multiple bonds and Si-bonded hydrogen atoms. It is also possible for the silicone compositions according to the invention to comprise all three components (A), (B) and (C).

If siloxanes (C) are used, these are preferably those composed of units of the general formulae (IV), (V) and (VI)

R⁴_{f}SiO_{4/2} (IV)

R⁴_{g}R⁵SiO_{3-g/2} (V)

R⁴ₕHSiO_{3-h/2} (VI)
where
R⁴ and R⁵ have the definition given for them above,
f is 0, 1, 2 or 3,
g is 0, 1 or 2 and
h is 0, 1 or 2,
with the proviso that there are at least two radicals R⁵ and at least two Si-bonded hydrogen atoms per molecule.

Examples of organopolysiloxanes (C) are those composed of SiO_{4/2}, R⁴₃SiO_{1/2}, R⁴₂R⁵SiO_{1/2} and R⁴₂HSiO_{1/2} units, known as MQ resins, where these resins may additionally comprise R⁴SiO_{3/2} and R⁴₂SiO units, and linear organopolysiloxanes essentially consisting of R⁴₂R⁵SiO_{1/2}, R⁴₂SiO and R⁴HSiO units with R⁴ and R⁵ having the definition given above.

The organopolysiloxanes (C) preferably have an average viscosity of 0.01 to 500 000 Pa·s, particularly preferably 0.1 to 100 000 Pa·s, in each case at 25° C., measured in accordance with DIN EN ISO 3219:1994 and DIN 53019 using a calibrated rheometer with a cone/plate system, cone CP50-2 with an opening angle of 2° and a shear rate of 1 s⁻¹.

Organopolysiloxanes (C) are commercially available or can be prepared by standard methods.

Addition-crosslinking silicone compositions according to the invention
may be selected from the group comprising
   at least one each of compounds (A), (B) and (D),
   at least one each of compounds (C) and (D), and
   at least one each of compounds (A), (B), (C) and (D),
where
(A) is an organic compound or an organosilicon compound comprising at least two radicals having aliphatic carbon-carbon multiple bonds,
(B) is an organosilicon compound comprising at least two Si-bonded hydrogen atoms,
(C) is an organosilicon compound comprising Si—C-bonded radicals having aliphatic carbon-carbon multiple bonds and Si-bonded hydrogen atoms, and
(D) is a hydrosilylation catalyst.

The silicone composition usually comprises 30-95% by weight, preferably 30-80% by weight and particularly preferably 40-70% by weight of (A), based on the total mass of the silicone composition.

The silicone composition usually comprises 0.1-60% by weight, preferably 0.5-50% by weight and particularly preferably 1-40% by weight of (B), based on the total mass of the silicone composition.

If the silicone composition comprises component (C), there is usually 30-95% by weight, preferably 30-80% by weight, particularly preferably 40-70% by weight of (C) in the formulation, based on the total mass of the silicone composition.

The amount of component (D) may be between 0.1 and 1000 parts per million (ppm), 0.5 and 100 ppm or 1 and 50 ppm of the platinum group metal, depending on the total weight of the components.

The amounts of all components present in the silicone composition are selected such that in total they do not exceed 100% by weight, based on the total mass of the silicone composition.

Hydrosilylation catalysts (D) used may be all catalysts known from the prior art. Component (D) may be a platinum group metal, for example platinum, rhodium, ruthenium, palladium, osmium or iridium, an organometallic compound or a combination thereof. Examples of component (D) are compounds such as hexachloroplatinum(IV) acid, platinum dichloride, platinum acetylacetonate and complexes of said compounds encapsulated in a matrix or a core/shell-type structure. The platinum complexes with low molecular weight of the organopolysiloxanes include 1,3-diethenyl-1,1,3,3-tetramethyldisiloxane complexes with platinum. Further examples are platinum-phosphite complexes, platinum-phosphine complexes or alkyl-platinum complexes. These compounds may be encapsulated in a resin matrix.

The concentration of component (D) is sufficient for catalyzing the hydrosilylation reaction of components (A) and (B) on contact, in order to produce the heat required here in the process described. The amount of component (D) may be between 0.1 and 1000 parts per million (ppm), 0.5 and 100 ppm or 1 and 50 ppm of the platinum group metal, depending on the total weight of the components. The curing rate may be low if the constituent of the platinum group metal is below 1 ppm. The use of more than 100 ppm of the platinum group metal is uneconomic or may lower the stability of the adhesive formulation.

In the case of two-component systems, use is preferably made of the Karstedt catalyst (=platinum-1,3-divinyl-1,1,3,3-tetramethyldisiloxane complex). In the case of one-component systems, use is preferably made of platinum-phosphite complexes, as disclosed for example in EP 2050768 A.

The term CNT refers to carbon nanotubes. These are nanomaterials that are in the form of hollow cylinders and consist of hexagonal carbon structures. Those skilled in the art are not restricted when choosing CNTs; here they may use any CNTs that are commercially available or can be produced using processes known from the literature.

The CNTs are used in a content in the range from 0.1-5% by weight based on the total weight of the composition; a content in the range from 0.1-3% by weight is preferred.

Preference is given to using CNTs with an average diameter of 1-50 nm and an aspect ratio (ratio of length to diameter L/D) of 10-10 000.

SWCNTs (SWCNT=single-walled carbon nanotubes) or MWCNTs (MWCNTS=multi-walled carbon nanotubes) may be used, with MWCNTs being preferred.

It is possible to use carbon blacks in all available and known modifications, such as furnace blacks, thermal blacks, gas blacks, channel blacks and acetylene blacks. It is of course also possible to use mixtures of different carbon blacks. Use is made according to the invention of carbon blacks which have a BET surface area of at most 300 m²/g in accordance with ASTM D6556. The content of carbon black is preferably 0.5% to 20% by weight and particularly preferably 0.5% to 3.0% by weight, based on the total weight of the silicone elastomer composition according to the invention.

The masses described may optionally comprise all further additives that are known to those skilled in the art from the prior art for addition-crosslinkable compositions. These additives may be, for example, rheological additives, inhibitors, light stabilizers, flame retardants, dispersing aids, heat stabilizers etc.

The present invention further provides for the production of the electrically conductive, crosslinking silicone elastomer composition according to the invention, characterized in that,
a) in the case of one-component systems, all components are mixed in one or in multiple steps and a pressure filtration is then performed through a metal mesh with a mesh size of at most 200 μm, or in that,
b) in the case of two-component systems, only the components of the A or B composition are mixed in each case in one or in multiple steps and in each case a pressure filtration of the A or B composition is then performed through a metal mesh with a mesh size of at most 200 μm.

The metal mesh used in the pressure filtration preferably has a mesh size of at most 100 μm.

The methods for mixing the components and for the pressure filtration and the apparatuses that can be used therefor are sufficiently known to those skilled in the art from the prior art.

By way of example, the dispersion is effected using a roll mill, kneader or particularly a dissolver (high-speed mixer), with a scraper usually additionally being used in order to achieve a uniform distribution of the conductive fillers. It is preferable to use a planetary dissolver having a scraper. It is particularly preferable to use a vacuum planetary dissolver having a scraper and a beam stirrer. Dissolver disks having any desired arrangement and number of teeth may be used.

It is undoubtedly surprising that the filter mesh does not become clogged when a paste comprising particles with a high aspect ratio (L/D>10) is passed through it. In addition, it was to be expected that the filtration step would have a negative effect on the electrical properties of the material. This is not the case: Both the electrical resistance of the uncrosslinked printing ink and the electrical behavior of the vulcanized sample remain constant when stretched.

The invention further provides for the use of the conductive crosslinking silicone elastomer composition according to the invention as electrically conductive printing ink in contactless printing processes to produce electrically conductive elastomers on elastic supports.

If the electrically conductive, crosslinking silicone elastomer composition according to the invention is used as printing ink for example in a contactless printing process, this produces a printed image which has a smooth surface free of jags. This is a crucial advantage if multilayer systems are to be produced, in which the conductive material is to be inserted between further layers, for example by way of lamination or overlayering.

Contactless printing processes have the advantage that the printing substrate experiences as low a mechanical load as possible during the printing process. The electrically conductive, crosslinking silicone elastomer composition according to the invention may be used as printing ink for other contactless printing processes, such as spraying processes, drop-on-demand processes or laser transfer printing (LIFT process). It is preferably used in laser transfer printing (LIFT process).

The electrically conductive, crosslinking silicone elastomer composition according to the invention is particularly preferably suitable as printing ink for printing electrodes for dielectric elastomer sensors, actuators and generators and EAP layer systems.

The invention therefore further provides electrically conductive films with a layer thickness of at most 200 μm, produced from electrically conductive, crosslinking silicone elastomer composition comprising:
0.5% to 3.0% by weight of carbon black with a BET surface area of at most 300 m²/g,
0.1% to 3.0% by weight of carbon nanotubes (CNTs).

The invention therefore further provides electrically conductive films produced from electrically conductive, crosslinking silicone elastomer composition comprising:
0.5% to 3.0% by weight of carbon black with a BET surface area of at most 300 m²/g,
0.1% to 3.0% by weight of carbon nanotubes (CNTs), characterized in that the film has been produced using a contactless printing process.

In one preferred embodiment, the electrically conductive films with a layer thickness of at most 200 μm, produced from electrically conductive, crosslinking silicone elastomer composition comprising:
0.5% to 3.0% by weight of carbon black with a BET surface area of at most 300 m²/g,
0.1% to 3.0% by weight of carbon nanotubes (CNTs), are characterized in that the film has been produced using a contactless printing process.

Preferably, the electrically conductive films display a stretching factor of the relative resistance increase R/R₀ of less than or equal to 1.5.

### EXEMPLARY EMBODIMENTS

The examples that follow describe how the present invention may be performed in principle but without limiting said invention to what is disclosed therein.

The examples that follow were performed at a pressure of the ambient atmosphere, i.e. at about 1013 hPa, and at room temperature, i.e. about 23° C., or a temperature established upon combining the reactants at room temperature without additional heating or cooling.

### Example

### Chemicals:

CNTs LUCAN BT1001M, manufacturer LG Chem Ltd., average diameter according to manufacturer specifications: 10 nm

To produce the carbon black premixes A, B and C, 5% by weight of the corresponding carbon black was incorporated into 95% by weight of ViPo 1000 on a three-roll mill. A three-roll mill from EXAKT (50 l model) was used. The roll nip was set to the minimum distance. The carbon blacks used are:

Carbon black A: Birla Conductex 7055 Ultra (BET 55 g/m², OAN 170 cm³/100 g).

Carbon black B: Ensaco 260G (BET 68 g/m², OAN 190 ml/100 g)

Carbon black C: Ketjenblack EC-600JD (available from Nouryon, BET 1400 g/m², QAN 495 cm³/100 g).

The BET measurement was performed by means of gas adsorption using nitrogen in accordance with ASTM D6556. The QAN values (oil absorption number) are manufacturer specifications.

ViPo 1000: Vinyldimethylsiloxy-terminal polydimethylsiloxane having a viscosity of 1000 mPa*s, available from Gelest Inc. under the product name DMS-V31 (Gelest catalog).

HPo 1000: Hydridodimethylsiloxy-terminal polydimethylsiloxane having a viscosity of 1000 mPa*s, available from Gelest Inc. under the product name DMS-H31 (Gelest catalog).

The crosslinker used was an α,ω-dimethylhydrogensiloxy-poly(dimethyl-methylhydrogen)siloxane (viscosity of 130-200 mm²/s; 0.145-0.165% by weight of H).

For one-component systems, the hydrosilylation catalyst selected was a platinum complex with phosphite ligands, as described in EP2050768B1 (catalyst 6).

1-Ethynyl-1-cyclohexanol is available from Sigma Aldrich (CAS number: 78-27-3).

### Viscosity Measurement:

The viscosity measurements were performed on an air-bearing-mounted MCR 302 rheometer from Anton Paar at 25° C. A cone/plate system (25 mm, 2⁰) with a gap size of 105 μm was used. The excess material was removed (trimmed) with a spatula at a gap distance of 115 μm. The cone was then moved to a gap distance of 105 μm so as to fill the entire gap. Before each measurement, a “pre-shear” is performed in which the shear history resulting from sample preparation, application and trimming is erased. The pre-shear is performed for 60 seconds at a shear rate of 10 s⁻¹, followed by a rest period of 300 seconds. The shear viscosity is determined by means of a step profile in which the sample is sheared at a constant shear rate of 1 s⁻¹, 10 s⁻¹ and 100 s⁻¹ for 100 seconds in each case. A reading is recorded every 10 seconds, resulting in 10 measurement points per shear rate. The average of these 10 measurement points gives the shear viscosity at the respective shear rate.

The storage modulus G′ was determined by means of an amplitude test. In this oscillation test, the amplitude γ is varied from 0.01% to 1000% (at an angular frequency ω of 10 s⁻¹, logarithmic ramp, 30 measurement points). The linear viscoelastic (LVE) region is typically found at low amplitude values, in which region G′, if plotted double-logarithmically against γ, has a plateau value. The plateau value is the storage modulus G′ to be determined.

### Resistance Measurement:

A four-conductor measurement does not measure the contact resistance since the current is applied at two contacts and the voltage U of the current I_{U} that has already flowed through the sample is measured at two further contacts.

$$R = \frac{U}{{I}_{U}} [ Ω ]$$

The resistance R of unvulcanized siloxanes is measured using the model 2110 5½ digit multimeter from Keithley Instruments and a manufactured measuring apparatus made of natural PP and stainless steel—(1.4571) electrodes. The measuring instrument is connected to the electrodes by means of brass contacts and laboratory leads. The measuring apparatus is a mold with defined dimensions for L×W×H of 16 cm×3 cm×0.975 cm, into which the siloxane is spread for measurement. The two outer flat electrodes are attached at a distance of 16 cm, thus ensuring that the current flows through the entire sample. The two point electrodes with a diameter of 1 cm are arranged in the base plate at a distance of 12 cm (1) and measure the voltage. The specific resistance is calculated from the measured resistance R using the following formula.

$$ρ = \frac{R \cdot h \cdot w}{l} [ Ω cm ] ,$$

using sample height h [cm], sample width w [cm] and electrode distance 1 [cm] (here: h=0.975 cm, w=3 cm, 1=12 cm).
Change in Resistance with Stretching (R/R₀)

In accordance with ISO 37, the printing inks were vulcanized in the form of a 2 mm plate and the type 1 dumbbell specimen was punched. The test specimen is subjected to a four-conductor measurement. Said test specimen is clamped centrally between two electrically conductive clamping jaws, such that their distance from one another is 84.0 mm. The clamping jaws, representing the two outer electrical contacts, are structured, whereby a penetration effect into the material (piercing) is achieved as a result of the structure.

The two inner contacts are prepared by positioning two quick clamps 29.5 mm away from the closest clamping jaw in each case and at a distance of 25 cm from one another. The two inner measuring clamps are pretreated with silver conductive paste. The resistance thus measured without stretching (L=L₀) is R₀. The two outer clamping jaws additionally enable the uniaxial stretching of the test specimen and thus the measurement of the resistance R of the printed electrode in the case of stretching (L−L₀)/L₀=50%.

### Mixing Methods:

The mixtures were produced in a Labotop 1LA from PC Laborsystem GmbH with a 1-liter capacity at a reduced pressure of 300 mbar and room temperature. The tools used were a dissolver disk (14 teeth, teeth at 90° to the disk, diameter 52 cm), a beam stirrer (standard tool) and a scraper with temperature measurement.

### Example 1 Production of Printing Ink 1

In a Labotop 1LA laboratory mixer from PC Laborsystem GmbH with toothed dissolver disk (diameter 52 mm), 1.2% by weight of CNTs (6.0 g) and 200 g of the carbon black premix A (corresponding to 2.0% by weight of carbon black A in the final formula) were mixed into a mixture of ViPo 1000 (124 g), HPo 1000 (150 g), crosslinker (20.0 g), Pt catalyst (0.4 g) and 1-ethynyl-1-cyclohexanol (30 mg) for 60 minutes at room temperature, 2000 rpm (dissolver) and 200 rpm (beam stirrer). A homogeneous, black paste was obtained.

### Example 2 Production of Printing Ink 2

The printing ink was produced analogously to printing ink 1 in Example 1, with the difference that carbon black premix B was used.

### Example 3 Production of Printing Ink 3

In a Labotop 1LA laboratory mixer from PC Laborsystem GmbH with toothed dissolver disk (diameter 52 mm), 1.5% by weight of CNTs (7.5 g) and 200 g of the carbon black premix A (corresponding to 2.0% by weight of carbon black A in the final formula) were mixed into a mixture of ViPo 1000 (124 g), HPo 1000 (148 g), crosslinker (20.0 g), Pt catalyst (0.4 g) and 1-ethynyl-1-cyclohexanol (30 mg) for 60 minutes at room temperature, 2000 rpm (dissolver) and 200 rpm (beam stirrer). A homogeneous, black paste was obtained.

### Example 4 Production of Printing Ink 4

The printing ink was produced analogously to printing ink 3 in Example 3, with the difference that carbon black premix B was used.

### Example 5 Production of Printing Ink 5 (Non-Inventive)

In a Labotop 1LA laboratory mixer from PC Laborsystem GmbH with toothed dissolver disk (diameter 52 mm), 0.8% by weight of CNTs (4.0 g) and 200 g of the carbon black premix C (corresponding to 2.0% by weight of carbon black C in the final formula) were mixed into a mixture of ViPo 1000 (108 g), HPo 1000 (154 g), crosslinker (20.0 g), Pt catalyst (0.4 g) and 1-ethynyl-1-cyclohexanol (30 mg) for 60 minutes at room temperature, 2000 rpm (dissolver) and 200 rpm (beam stirrer). A homogeneous, black paste was obtained.

### Example 6 Production of Printing Ink 6 (Non-Inventive)

The printing ink was produced analogously to printing ink 1 in Example 1, with the difference that carbon black premix C was used.

### Example 7 Production of Printing Ink 7 (Non-Inventive)

The printing ink was produced analogously to printing ink 3 in Example 3, with the difference that carbon black premix C was used.

### Example 8 Production of Printing Ink 8 (Non-Inventive)

In a Labotop 1LA laboratory mixer from PC Laborsystem GmbH with toothed dissolver disk (diameter 52 mm), 2.0% by weight of CNTs (10 g) were mixed into a mixture of ViPo 1000 (316 g), HPo 1000 (153 g), crosslinker (20.0 g), Pt catalyst (0.4 g) and 1-ethynyl-1-cyclohexanol (30 mg) for 60 minutes at room temperature, 2000 rpm (dissolver) and 200 rpm (beam stirrer). A homogeneous, black paste was obtained.

### Example 9 Production of Printing Ink 9 (Non-Inventive)

In a Labotop 1LA laboratory mixer from PC Laborsystem GmbH with toothed dissolver disk (diameter 52 mm), 1.2% by weight of CNTs (6.0 g) were mixed into a mixture of ViPo 1000 (319 g), HPo 1000 (155 g), crosslinker (20.0 g), Pt catalyst (0.4 g) and 1-ethynyl-1-cyclohexanol (30 mg) for 60 minutes at room temperature, 2000 rpm (dissolver) and 200 rpm (beam stirrer). A homogeneous, black paste was obtained.

The table that follows compares the amounts of CNT and carbon black used in the examples and the results of the measurements.

| | CNT | | | Viscosity | | spec. | R/R₀ |
|---|---|---|---|---|---|---|---|
| Printing | (% by | Carbon black | Carbon | at 10 s⁻¹/ | G′ | resistance | at 50% |
| ink no. | weight) | (% by weight) | black | [Pas] | [kPa] | [Ω * cm] | stretch |
| 1 | 1.2 | 2.0 | A | 43 | 5.2 | 9.7 | 1.2 |
| 2 | 1.2 | 2.0 | B | 53 | 7.1 | 8.8 | 1.2 |
| 3 | 1.5 | 2.0 | A | 56 | 11 | 7.1 | 1.2 |
| 4 | 1.5 | 2.0 | B | 50 | 8.6 | 9.3 | 1.2 |
| 5 | 0.8 | 2.0 | C | 79 | 11 | 8.8 | 1.6 |
| 6 | 1.2 | 2.0 | C | 100 | 19 | 6.8 | 1.2 |
| 7 | 1.5 | 2.0 | C | 177 | 29 | 4.9 | 1.2 |
| 8 | 2 | 0 | — | 94 | 14 | 7.0 | 1.2 |
| 9 | 1.2 | 0 | — | 38 | 4.5 | 17 | 1.3 |

The results show that for printing inks 1, 2, 3 and 4 the viscosity value of 60 Pas at a shear rate of 10 s⁻¹ is not exceeded, and at the same time these inks have a high electrical conductivity with a specific resistance of less than 10 Ω*cm. In contrast, printing inks 5, 6 and 7, which are not subject matter of the present invention, have a higher viscosity. If R/R₀ at 50% stretch is not to exceed the value of 1.5, the viscosity of the printing inks having high-conductivity carbon black with a BET of 1400 g/m² (printing inks 6 and 7) is at least 100 Pas. The carbon black-free printing inks feature either a high viscosity (no. 8) or low conductivity (no. 9). In summary, it is apparent that only printing inks 1, 2, 3 and 4, which comprise a carbon black with a low BET surface area, combine good electrical properties with low viscosity.

1-9. (canceled)

10. An electrically conductive, crosslinking silicone elastomer composition comprising
0.5% to 3.0% by weight of carbon black with a BET surface area of at most 300 m²/g,
0.1% to 3.0% by weight of carbon nanotubes (CNTs), and
no solvent.

11. The electrically conductive, crosslinking silicone elastomer composition as claimed in claim 10, characterized in that it is an electrically conductive, addition-crosslinking silicone elastomer composition, and comprises the following components:
(A) at least one linear compound comprising radicals having aliphatic carbon-carbon multiple bonds,
(B) at least one linear organopolysiloxane compound having Si-bonded hydrogen atoms,
or, instead of (A) and (B) or in addition to (A) and (B),
(C) at least one linear organopolysiloxane compound comprising Si—C-bonded radicals having aliphatic carbon-carbon multiple bonds and Si-bonded hydrogen atoms, and
(D) at least one hydrosilylation catalyst.

12. A process for producing the electrically conductive, crosslinking silicone elastomer composition as claimed in claim 11, characterized in that,
a) in the case of one-component systems, all components are mixed in one or in multiple steps and a pressure filtration is then performed through a metal mesh with a mesh size of at most 200 μm, or in that,
b) in the case of two-component systems, only the components of the A or B composition are mixed in each case in one or in multiple steps and in each case a pressure filtration of the A or B composition is then performed through a metal mesh with a mesh size of at most 200 μm.

13. The use of the conductive crosslinking silicone elastomer composition as claimed in claim 10 as an electrically conductive printing ink in contactless printing processes to produce electrically conductive elastomers on elastic supports.

14. The use as claimed in claim 13, characterized in that the contactless printing process is laser transfer printing.

15. The use as claimed in claim 13, characterized in that the produced electrically conductive elastomers on elastic supports are electrodes for dielectric elastomer sensors, actuators and generators and EAP layer systems.

16. An electrically conductive film with a layer thickness of at most 200 μm, produced from an electrically conductive, crosslinking silicone elastomer composition comprising
0.5% to 3.0% by weight of carbon black with a BET surface area of at most 300 m²/g, and
0.1% to 3.0% by weight of carbon nanotubes (CNTs).

17. The electrically conductive film as claimed in claim 16, characterized in that the film has been produced using a contactless printing process.

18. An electrically conductive film produced from an electrically conductive, crosslinking silicone elastomer composition comprising
0.5% to 3.0% by weight of carbon black with a BET surface area of at most 300 m²/g,
0.1% to 3.0% by weight of carbon nanotubes (CNTs),
characterized in that the film has been produced using a contactless printing process.
